(19) United States
(12) Patent Application Publication
(10) Pub. No.: US 2010/0268497 A1
(43) Pub. Date: Oct. 21, 2010

(54) PORTABLE SYSTEM WITH FUNCTION OF MEASUREMENT AND MEASUREMENT METHOD THEREBY

(76) Inventor: Ke-Ren PENG, Xi'an (CN)

Correspondence Address: Muncy, Geissler, Olds & Lowe, PLLC, 4000 Legato Road, Suite 310, FAIRFAX, VA, 22033, US

(21) Appl. No.: 12/764,279

(22) Filed: Apr. 21, 2010

(30) Foreign Application Priority Data
Apr. 21, 2009 (TW) 098113150

(51) Int. Cl. G06F 19/00; G01R 27/00; G01R 13/00; G01R 23/16

(52) U.S. Cl. 702/65; 702/66; 702/67; 702/76

(57) ABSTRACT

A portable system having a function of measurement includes a conductive structure and a mobile communication device. The conductive structure is plugged into a earphone socket of the mobile communication device for measuring a electric signal of an object. Next, the result of the measurement can be shown on a display or broadcasted on a speaker of the mobile communication device.

This application claims the benefit of Taiwan Patent Application Serial No. 098113150, filed Apr. 21, 2009, the subject matter of which is incorporated herein by reference.

### FIELD OF THE INVENTION

The present invention relates to a portable system having a function of measurement, and particularly relates to a portable system including a conductive structure and a mobile communication device to execute electrical measurement for an object.

### BACKGROUND OF THE INVENTION

Common measuring tools, such as multimeter, oscilloscope, spectral analyser, etc., are commonly used by engineers. However, since these measuring instruments are large, it is inconvenient for the engineers to carry these instruments with them. As a result, it often brings more inconvenience to the engineers when they execute certain measurement or test items without carrying specified measurement instruments or equipment with them.

### SUMMARY OF THE INVENTION

Based on above description, in order to solve the problems of not being able to carry measuring instruments needed around, the objective of the present invention is to provide a portable system having a function of measurement by means of mobile communication devices which are often carried by ordinary people, and by plugging in a simple conductive structure. As a result, users can carry a portable system of the present invention with them to measure an object anytime.

To achieve the objective, the present invention provides a portable system with a function of measurement, including a conductive structure and a mobile communication device. The conductive structure includes a conductive component and a conductive plug. The conductive component measures an object to produce a measurement signal and the conductive plug is electrically engage with the conductive component.

The mobile communication device includes a signal socket, a data processing module, and a central processing module. The signal socket is used to electrically engage with the conductive plug; the data processing module is electrically connected with the signal socket and analyzes the measurement signal to produce an analysis signal. The central processing module is electrically connected with the data processing module and manages the analysis signal to produce a resultant signal.

To achieve the objective, the present invention also provides a measurement method being executed by the portable system with the function of measurement, the method including: step (a) causing a conductive structure to engage with a signal socket of a mobile communication; step (b) entering a measuring instrument mode; step (c) bringing the conductive structure into contact with an object to produce a measurement signal; and step (d) analyzing the measurement signal into an analysis signal by a data processing module of the mobile communication device.

Based on above background, it is just necessary for the users to carry basic portable measuring instruments with them to measure objects anytime by their mobile communication devices and the conductive structure.

### BRIEF DESCRIPTION OF THE DRAWINGS

The accompanying drawings are included to provide a further understanding of the present invention, and are incorporated in and constitute a part of this specification. The drawings illustrate embodiments of the invention and, together with the description, serve to explain the principals of the present invention.

FIG. 1 is a perspective view of a portable system with a function of measurement in accordance with a preferred embodiment of the present invention.

FIG. 2 is a functional block diagram of the portable system in accordance with the preferred embodiment of the present invention.

FIG. 3 is a partial circuit diagram showing a portable system in accordance with the preferred embodiment of the present invention.

FIG. 4 is a flow chart showing a measurement method applicable to a portable system in accordance with the preferred embodiment of the present invention.

### DETAILED DESCRIPTION OF THE PREFERRED EMBODIMENTS

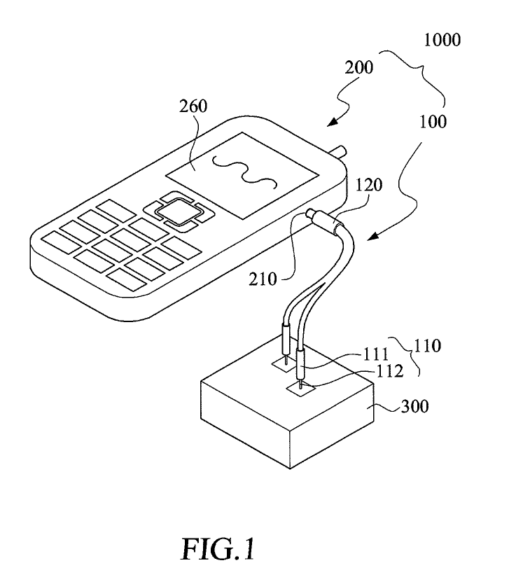

Refer to FIG. 1, which is a perspective view of a portable system with a function of measurement in accordance with a preferred embodiment of the present invention, wherein a portable system 100 includes a conductive structure 100 and a mobile communication device 200.

The conductive structure 100 includes a conductive component 110 and a conductive plug 120. The conductive component 110 is electrically connected with the conductive plug 120 and may be a pen-shape metal piece. The conductive component 110 includes a gripping holder 111 and a metal rod piece 112. The metal rod piece 112 is installed inside the gripping holder 111, and outwardly protruded from the gripping holder 111 for contacting an object 300.

The mobile communication device 200 includes a signal socket 210 and a display 260. The signal socket 210 is used to engage with the conductive plug 120. When the conductive component 110 is operated to measure electrical parameters of the object 300, the results are displayed on the display 260 of the mobile communication device 200.

Thus, users can use the mobile communication device 200, that the users may usually carry with in daily life, to connect the conductive structure 100, so as to execute electrical detection.

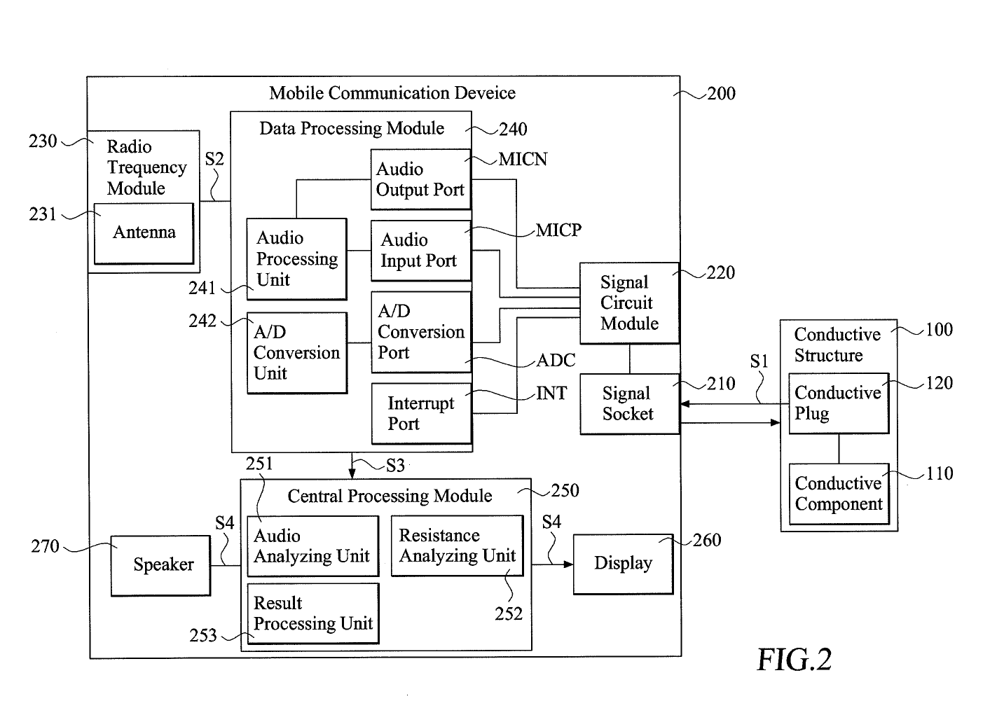

Refer to FIG. 2, which is a functional block diagram showing the portable system in accordance with the preferred embodiment of the present invention. The mobile communication device 200 may be selected from the group consisting of a mobile phone, a smart phone, a personal digital assistant (PDA) or and notebook; i.e. the mobile communication device 200 may be a mobile phone, a smart phone, a personal digital assistant (PDA), a notebook or a multiple-function communication device, which can be widely used in daily life.

The mobile communication device 200 includes a signal socket 210, a signal circuit module 220, a radio frequency module 230, a data processing module 240, a central processing module 250, a display 260 and a speaker 270.

The signal socket 210 can be selected from the group consisting of an earphone socket, a headset socket and a microphone socket; i.e., the signal socket 210 may be an earphone socket, a headset socket, a microphone socket or the combination thereof. The signal socket 210 can be connected to an earphone, a headset or a microphone. According to the preferred embodiment of the present invention, the signal socket 210 is used to electrically engage with the conductive plug 120, so as to receive and transmit a measurement signal S1 measured by the conductive component 110.

The signal circuit module 220 may be composed of a electronic circuit. The signal circuit module 220 is electrically connected with the data processing module 240 and the signal socket 210. The signal circuit module 220 is served for signal transmission between the data processing module 240 and the signal socket 210.

The radio frequency module 230 includes an antenna 231. The radio frequency module 230 is electrically connected with the data processing module 240, and receives and sends a wireless signal S2, so that the mobile communication device 200 can perform wireless communication. Due to that wireless communication technologies are common technologies widely applied to many mobile communication devices, the related descriptions are not further disclosed hereafter.

The data processing module 240 includes a processing chip and relevant circuits. The data processing module 240 is electrically connected with the radio frequency module 230 and the signal circuit module 220 respectively. The data processing module 240 is used to receive the measurement signal S1, and further to analyze the measurement signal S1 into an analysis signal S3. In another preferred embodiment of the present invention, the analysis signal S3 is sent and transmitted from the radio frequency module 230 to another remote analysis device (not shown) to be further analyzed, such that the present invention also can provide an additional function of remote cooperative working.

The data processing module 240 includes an audio output port (MICN), an audio input port (MICP), an A/D conversion port (ADC), an interrupt port (INT), an audio processing unit 241 and an A/D conversion unit 242. The audio processing unit 241 is electrically connected with the audio input port (MICP) and the audio output port (MICN). When a headset is engaged into the signal socket 210, the audio processing unit 241 receives and transmits analog vocal signals of the headset. The audio processing unit 241 performs time domain and frequency domain analyses of the analog vocal signals. The A/D conversion unit 242 is electrically connected with the A/D conversion port (ADC). The A/D conversion unit 242 performs analyses on the range of voltages to convert an analog signal into a digital signal. When an audio test is performed in accordance with the present invention, the audio processing unit 241 receives the measurement signal S1 through the audio input port (MICP) and performs time domain and frequency domain analyses of the measurement signal S1. When a resistance test is performed in accordance with the present invention, the A/D conversion unit 242 receives the measurement signal S1 through the A/D conversion port (ADC) and performs voltage measurements for the measurement signal S1, so as to calculate the resistance value.

The central processing module 250 includes a central processor unit (CPU) and relevant circuits. The central processing module 250 is electrically connected with the data processing module 240, and analyzes the analysis signal S1 to produce a resultant signal S4. The central processing module 250 includes an audio analyzing unit 251, a resistance analyzing unit 252 and a result processing unit 253. The audio analyzing unit 251, the resistance analyzing unit 252 and the result processing unit 253 may be a computer program. When the mobile communication device 200 is a smart phone, program codes of the audio analyzing unit 251, the resistance analyzing unit 252 and the result processing unit 253 can be uploaded and installed in the mobile communication device 200. When the mobile communication device 200 is an ordinary mobile phone, the program codes can be embedded in a storage device of the mobile phone in the beginning that the mobile phone is manufactured. Therefore, the present invention has the function of performing analyses and measurements without changing hardware of the mobile communication device 200. When an audio test is performed in accordance with the present invention, the audio analyzing unit 251 is cooperated with the audio processing unit 241 of the data processing module 240 to perform time domain and frequency domain analyses of the measurement signal S1. When a resistance test is performed in accordance with the present invention, the resistance analyzing unit 252 is cooperated with the A/D conversion unit 242 of the data processing module 240 to perform a resistance analysis for the measurement signal S1. The result processing unit 253 analyzes the analysis signal S1 into a resultant signal S4. In another preferred embodiment, the resultant signal S4 is sent and transmitted from the radio frequency module 230 to another remote display (not shown), and displayed thereon, such that the present invention can provide an additional function of remote cooperative working.

The display 260 is electrically connected with the CPU to display the resultant signal S4. For example, when the resultant signal S4 includes parameters of time domain and frequency domain, the waveform of the resultant signal S4 is shown on a figure (refer to FIG. 1).

The speaker 270 is electrically connected with the central processing module 250 to display the resultant signal S4. For example, when the resultant signal S4 includes a resistance value, the resistance value is broadcasted to users via sounds.

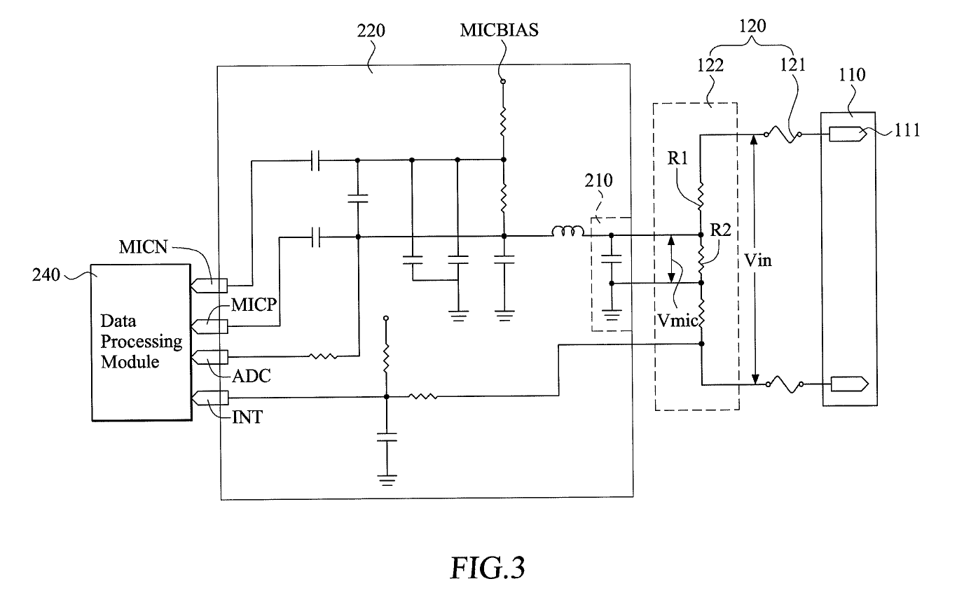

Refer to FIG. 2 and FIG. 3, FIG. 3 is a partial circuit diagram showing a portable system in accordance with the preferred embodiment of the present invention. The conductive component 110 includes two metal rod pieces 112 to individually contact an object 300 so as to measure the measurement signal S1 of the object 300.

The conductive plug 120 includes a fuse 121 and a voltage conversion module 122. Since an input voltage of the data processing module 240 of an ordinary mobile phone cannot exceed 2.8v, the voltage conversion module 122 is applied to reduce the voltage measured by the conductive component 110 when the voltage or the audio signal of the object 300 is measured. The voltage conversion module 122 includes an input terminal (Vin) and an output terminal (Vmic). The input terminal (Vin) is coupled to the conductive component 110, and the output terminal (Vmic) is coupled to the data processing module 240. The voltage conversion module 122 includes a voltage division circuit including a first resistance R1 and a second resistance R2. According to the present embodiment, if the resistance value of the first resistance R1 is 100KΩ and the resistance value of the second resistance R2 is 10 KΩ, according to an electricity formula of Vin=Vmic X (R1/R2+1), it can be known that Vin=11 Vmic. Therefore, for ordinary requirements of measurement, the voltage range measured by the input terminal (Vin) is in the range between −10V to 10V, and after being converted through the voltage conversion module 122, the voltage range measured by the output terminal (Vmic) is in the range between −V to V. As a result, it not only can meet the requirements of general measurements, but also can protect the circuit of the mobile communication device 200.

The fuse 121 is electrically connected with the voltage conversion module 122 and the conductive component 110 such that the circuit of the mobile communication device can be protected when the voltage received by conductive component 110 is greater than a critical voltage. The fuse 121 can be a self-recovery fuse. Normally, the fuse 121 is in a low impedance state, and a large current is generated so that a transient occurs and the low impedance state becomes the high impedance state when over-current (such as short-circuit) happens in a circuit. Under this situation, the circuit is cut off to protect the mobile communication device 200. After the breakdown is solved, the fuse 121 is self-recovered into its initial state.

The signal circuit module 220 is an earphone circuit embedded in ordinary mobile communication devices. The circuit of the signal circuit module 220 is electrically connected with the audio output port (MICN), the audio input port (MICP), the A/D conversion port (ADC), and the interrupt port (INT) of the data processing module 240, and is electrically connected with the output terminal (Vmic) of the voltage conversion module 122.

In a normal use state, if a headset (not shown) is not engaged into the signal socket 210, the headset is electrically connected with the data processing module 240, and the interrupt port (INT) generates an interrupt signal to the data processing module 240. When the data processing module 240 receives the interrupt signal, the audio processing unit 241 receives the analog voice signal of the headset through the audio input port (MICP) and transmits the analog voice signal to the headset from the audio output port (MICN) so as to perform communication. Due to that the technologies of the analog voice signal, processing the control signal, communicating by means of the mobile communication device 200 are commonly known in prior arts, the related descriptions are not further disclosed hereafter.

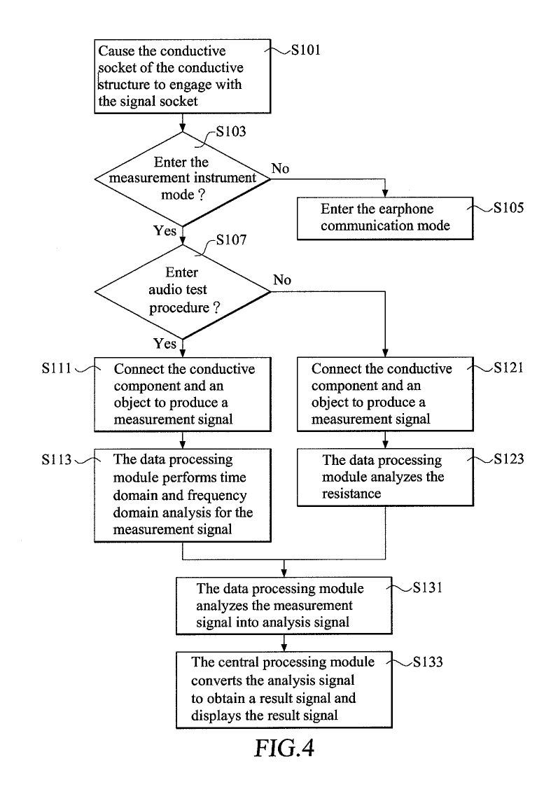

Refer to FIG. 4, which is a flow chart showing a measurement method applicable to a portable system in accordance with the preferred embodiment of the present invention. In the preferred embodiment of the present invention, when the conductive socket 120 of the conductive structure 100 is engaged with the signal socket 210 (S101). According to a present embodiment of the present invention, the conductive structure 100 is plugged into the signal socket 210. The interrupt port (INT) generates an interrupt signal to the data processing module 240, and then the data processing module 240 informs the central processing module 250 to display a screen of options on the display 260. Users can select whether to enter a measurement instrument mode or an earphone communication mode so that the central processing module 250 determines whether to enter the measurement instrument mode or the earphone communication mode (S103). According to another embodiment, if users do not select after a predetermined time, the system enters the earphone communication mode automatically or when the interrupt signal is generated; further more, it changes to enter the measurement instrument mode when users further select to enter the measurement instrument mode. In another embodiment, the measurement instrument mode further includes an audio test procedure and a resistance test procedure. The selections of operation, such as whether to enter the earphone communication mode, and performing the audio test procedure or the resistance test procedure, are displayed on the display. When users select to enter the earphone communication mode, ordinary communication is executed by the mobile communication device 200 (S105).

When users select to enter the measurement instrument mode, they can further select an audio test procedure and a resistance test procedure. The central processing module 250 determines whether to enter the audio test procedure and the resistance test procedure according to users' choice (S107).

Afterward, users can electrically connect the conductive component 110 and an object 300 to generate a measurement signal S1 (S111 or S121).

When performing an audio test procedure, an audio analysis unit 251 of the central processing module 250 controls the audio processing unit 241 of the data processing module 240 to perform time domain and frequency domain analysis for the measurement signal S1 (S113).

When performing a resistance test procedure, the resistance analysis unit 252 of the central processing module 250 controls the A/D conversion unit 242 of the data processing module 240 to execute voltage measurements so as to analyze the resistance. Moreover, the resistance of the object 300 can be obtained according to Ohm's law after a current-biased terminal (MICBIAS) of the signal circuit module 220 is turned on to form a circuit loop between the object 300, (S123).

The data processing module 240 analyzes the measurement signal 51 into an analysis signal S3 (S131). The central processing module 250 converts the analysis signal S3 to produce a resultant signal S4, and displays the resultant signal S4 on a display 260 or broadcasts the resultant signal S4 through a speaker 270 (S133).

Based on the above, it is just necessary for the users to carry basic portable measuring instruments with them to measure objects anytime by their mobile communication devices and the conductive structure.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A portable system comprising:
a conductive structure for measuring an object, the conductive structure comprising:
a conductive component for contacting the object to produce a measurement signal; and
a conductive plug electrically connected with the conductive component; and
a mobile communication device, comprising:
a signal socket used to electrically engage with the conductive plug to transmit the measurement signal;
a data processing module electrically connected with the signal socket and used to analyze the measurement signal into an analysis signal; and
a central processing module electrically connected with the data processing module and used to process the analysis signal to produce a resultant signal.

2. The portable system according to claim 1, wherein the conductive component comprises a pen-shape metal piece.

3. The portable system according to claim 1, wherein the mobile communication device is selected from the group consisting of a smart mobile phone and a personal digital assistant (PDA).

4. The portable system according to claim 1, wherein the signal socket is selected from the group consisting of an earphone socket, a headset socket and a microphone socket.

5. The portable system according to claim 1, wherein the conductive plug comprises a fuse.

6. The portable system according to claim 1, wherein the conductive plug comprises a voltage conversion module to adjust a voltage range received by the conductive component.

7. The portable system according to claim 1, wherein the central processing module further comprises an audio analyzing unit to cooperate with the data processing module to perform time domain or frequency domain analysis of the measurement signal.

8. The portable system according to claim 1, wherein the central processing module further comprises a resistance analyzing unit to cooperate with the data processing module to perform resistance analysis of the measurement signal.

9. The portable system according to claim 1, the central processing module analyzing and converting the analysis signal into the resultant signal.

10. The portable system according to claim 1, wherein the mobile communication device further comprises a display electrically connected to the central processing unit for displaying the resultant signal.

11. The portable system according to claim 1, wherein the mobile communication device further comprises a speaker electrically connected to the central processing unit for broadcasting the resultant signal.

12. The portable system according to claim 1, wherein the mobile communication device further comprise a radio frequency module electrically connected to the data processing module for transmitting the resultant signal to a remote display.

13. The portable system according to claim 1, wherein the mobile communication device further comprise a radio frequency module electrically connected to the data processing module for transmitting the analysis signal to a remote analysis device.

14. A measurement method applicable to a portable system comprising a mobile communication device and a conductive structure, the measurement method comprising the steps of:
(a) causing the conductive structure to engage with a signal socket of the mobile communication device;
(b) bringing the conductive structure into contact with an object to produce a measurement signal; and
(c) analyzing the measurement signal into an analysis signal, and converting the analysis signal into a resultant signal.

15. The measurement method according to claim 14, wherein the signal socket is selected from the group consisting of an earphone socket, a headset socket, and a microphone socket.

16. The measurement method according to claim 14, before the step (b), further comprising a step (a1) of determining whether an audio test procedure is entered.

17. The measurement method according to claim 16, after the step (b), further comprising a step (b1) of performing a time domain or frequency domain analysis of the measurement signal when entering the audio test procedure.

18. The measurement method claim 17, after the step (b1), further comprising a step (b2) of performing a resistance test procedure to direct a data processing module to perform a resistance analysis of the measurement signal when it is determined that the audio test procedure is entered in the step (a1).

19. The measurement method according to claim 14, wherein the resultant signal is displayed on a display.

20. The measurement method according to claim 14, wherein the resultant signal is broadcasted by a speaker.
